(19) United States
(12) Patent Application Publication
(10) Pub. No.: US 2003/0216042 A1
(43) Pub. Date: Nov. 20, 2003

(54) CMP slurry for oxide film and method of forming semiconductor device using the same

(76) Inventors: Sang Ick Lee, Kyoungki-do (KR); Hyung Hwan Kim, Kyoungki-do (KR)

Correspondence Address: MARSHALL, GERSTEIN & BORUN LLP, 6300 SEARS TOWER, 233 S. WACKER DRIVE, CHICAGO, IL, 60606, US

(21) Appl. No.: 10/331,359

(22) Filed: Dec. 30, 2002

(30) Foreign Application Priority Data
May 17, 2002 (KR) 2002-27539

(51) Int. Cl. H01L 21/302; H01L 21/461

(52) U.S. Cl. 438/689

(57) ABSTRACT

A chemical mechanical polishing(abbreviated as “CMP”) slurry composition for oxide films, and a method of forming a self-aligned floating gate of a flash memory device are disclosed for performing a CMP process using slurry having higher polishing selectivity to an oxide film than to a nitride film which is an etching barrier film.

### BACKGROUND

1. Technical Field

A chemical mechanical polishing (abbreviated as “CMP”) slurry composition for oxide films and a method of forming a self-aligned floating gate of a flash memory device are disclosed for performing a CMP process using slurry having higher polishing selectivity to an oxide film than to a nitride film which is an etching barrier film.

2. Description of the Related Art

Flash memory is a memory wherein a programming and an erasing operation are simultaneously performed while electrons are passing through a tunnel oxide film formed between a self-aligned floating gate and a semiconductor substrate. Flash memory is also a nonvolatile memory wherein stored information is not damaged even when power is turned off and the information can be freely inputted/outputted by an electrical method.

FIGS. 1a through 1g are diagrams illustrating processes of fabricating conventional self-aligned floating gates.

The reader will note that the thicknesses listed below for the various layers described below are approximation.

Referring to FIG. 1a, a pad oxide film 3 is formed at a thickness of 100 Å on a silicon substrate 1, and a pad nitride film 5 is sequentially formed at a thickness of 2500 Å on the pad oxide film 3.

Referring to FIG. 1b, while a selective polishing process using mask(not shown)is performed on the resultant structure, the pad nitride film 5 at a thickness of 2500 Å, the pad oxide film 3 at a thickness of 100 Å and the silicon substrate 1 at a thickness of 3000 Å are sequentially removed.

As a result, a pad nitride film pattern 5-1, a pad oxide film pattern 3-1 and a trench 7 are formed.

Referring to FIG. 1c, a isolation oxide film 9 is formed a thickness of 6000 Å from the pad nitride film pattern 5-1 on the entire surface including the trench 7.

Referring to FIG. 1d, a CMP process using the conventional CMP slurry for oxide film is performed on the isolation oxide film 9 using the pad nitride film pattern 5-1 as etching barrier, thereby an active region 11 is isolated.

Referring to FIG. 1e, the pad nitride film pattern 5-1 and the pad oxide film pattern 3-1 are selectively wet-etched until the substrate 1 is exposed, and then a tunnel oxide film 13 is formed on the exposed substrate 1.

Referring to FIG. 1f, a polysilicon 15a is formed on the tunnel oxide film 13 and isolation oxide film 9, at a thickness of 1700 Å with respect to the isolation oxide film 9.

Referring to FIG. 1g, a CMP process using an oxide film slurry is performed on polysilicon 15a until the isolation oxide film 9 is exposed to provide a floating gate 15.

As shown in FIG. 1d, the slurry used in performing a CMP process on the isolation oxide film 9 is common CMP slurry for oxide films with pH ranging from 7 to 8 including abrasives such as colloidal or fumed SiO₂. The slurry has polishing selectivity of nitride film:oxide film ranging from 1:2 to 1:4.

However, in the CMP process using the conventional CMP slurry, the isolation oxide film 9 is etched, a erosion effect is generated on the pad nitride film 5 and a dishing effect is generated on the oxide film 9 because the pad nitride film 5 and the isolation oxide film 9 have a small difference in an etching selectivity, thereby the thickness of the isolation oxide film 9 is differentiated.

This effect more frequently occurs as the isolation oxide film has the higher pattern concentration or larger pattern size.

In addition, the polysilicon 23a has an irregular thickness, because of the irregular thickness of the isolation oxide film 9. As a result, the reliability of devices is degraded.

There is also a problem in that the pad nitride film 5 should be more thickly stacked than required in order to obtain a predetermined thickness of a isolation oxide film.

### SUMMARY OF THE DISCLOSURE

CMP slurry having a better polishing selectivity to oxide films than to nitride films is disclosed.

As a result, the reliability of the device are improved by forming a self-aligned floating gate using the above CMP slurry.

A CMP slurry composition for an oxide film comprises a solvent, an abrasive and an additive.

The additive is selected form the group consisting of: a homo-polymer of hydrocarbon compound including carboxylic acid(—COOH), nitro(—NO₂) or amide(—NH—CO—) as a functional group; a copolymer of hydrocarbon compound including carboxylic acid(—COOH), nitro(—NO₂) or amide(—NH—CO—) as a functional group; and a mixture thereof,

wherein the composition has a pH ranging from 2 to 7.

The CMP slurry composition further comprises a pH adjusting agent. The pH adjusting agent is hydrochloric acid, and added in the slurry composition to have pH ranging from 2 to 7, more preferably from 4 to 7, because the slurry composition has high selectivity to oxide films under the acidic condition.

Accordingly, the added amount of hydrochloric acid is not specifically predetermined, but the proper amount of hydrochloric acid is determined to maintain the above pH range of the CMP slurry composition.

The solvent is distilled water or ultra pure water and the abrasive is Ceria(CeO₂), colloidal or fumed SiO₂.

The polymer as the additive has molecular mass ranging from 1000 to 10000.

The preceding functional group of carboxylic acid(—COOH), nitro(—NO₂) or amide(—NH—CO—) included in hydrocarbon compound may be changed into —OH, —C═O, —COO⁻, —NH₂, —NO, —NO₂ or —NHCO in the process of synthesis of polymer. Preferred the compounds including such a structure are selected from the group consisting of carboxymethylcellulose sodium salt, methyl vinyl ether, poly(acrylic acid), poly(ethylene glycol), polygalacturonic acid and combinations thereof, preferably alpha-cellulose, thereby resulting in improving selectivity of oxide films.

The CMP slurry composition has the CeO₂ is present in amount ranging from 0.5 to 2 weight parts based on 100 weight parts of the solvent and the additive is present in amount ranging from 0.1 to 1.5 weight parts based on 100 weight parts of the solvent.

The CMP slurry composition has the SiO₂ is present in amount ranging from 10 to 33, more preferably from 14 to 33 weight parts based on 100 weight parts of the solvent and the additive is present in amount ranging from 0.1 to 1.5, more preferably from 0.1 to 1 weight parts based on 100 weight parts of the solvent.

The CMP slurry composition for oxide films has polishing selectivity of nitride film:oxide film ranging from 1:20 to 1:200, more preferably from 50 to 200.

One disclosed method comprises:

(a) forming a pad oxide film and a pad nitride film on a substrate;

(b) selectively patterning the pad nitride film, a pad oxide film and a semiconductor in a predetermined depth, successively;

(c) depositing a isolation oxide film on the resultant; and

(d) performing a CMP process on to the entire surface of the resultant using a disclosed CMP slurry composition until the pad nitride film is exposed.

The CMP process of part (d) comprises two steps.

In the first step of performing a CMP process used a slurry for an oxide film having a selectivity ratio for nitride film : oxide film ranging from 1:2 to 1:4 until the isolation oxide film on the pad oxide film remains by a predetermined thickness; and

the second step of performing a CMP process using a slurry of the present invention until exposing the pad nitride film.

For instance, the first step is performed until the thickness oxide film on the pad nitride film becomes from 1 to 50%, more preferably from 16 to 20% relative to the thickness before the CMP process.

Here, the conventional slurry for oxide films is common CMP slurry for oxide films including abrasives such as colloidal or fumed SiO₂ and it has a pH ranging from 7 to 8. The slurry has a polishing selectivity of nitride film:oxide film ranging from 1:2 to 1:4.

### BRIEF DESCRIPTION OF THE DRAWINGS

FIGS. 1a through 1g are diagrams illustrating methods of fabricating conventional flash memory devices in accordance with the conventional art.

FIGS. 2a through 2g are diagrams illustrating methods of fabricating flash memory devices in accordance with the disclosed methods.

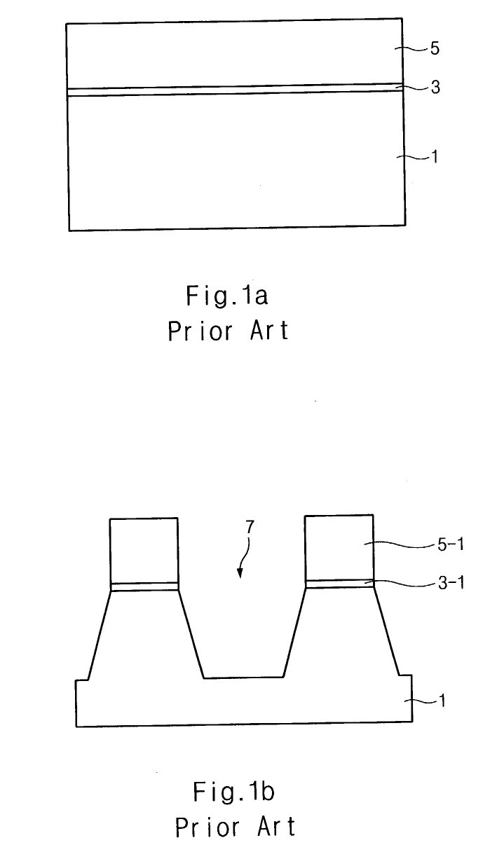

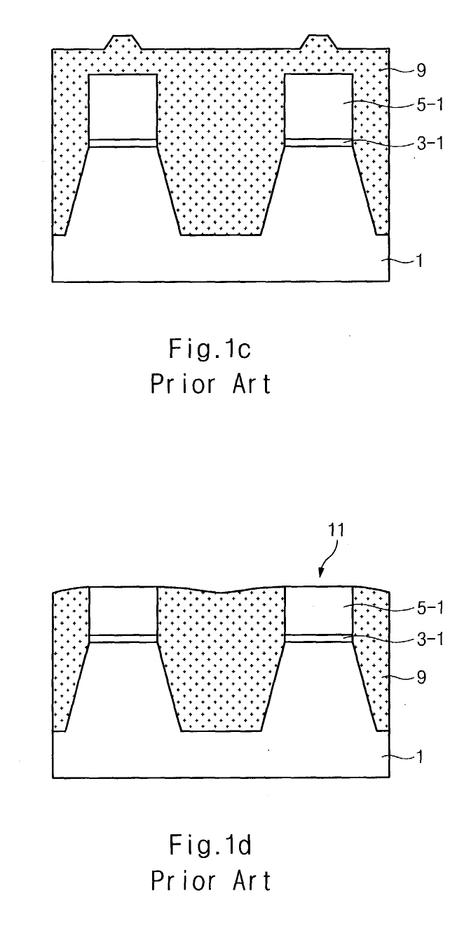

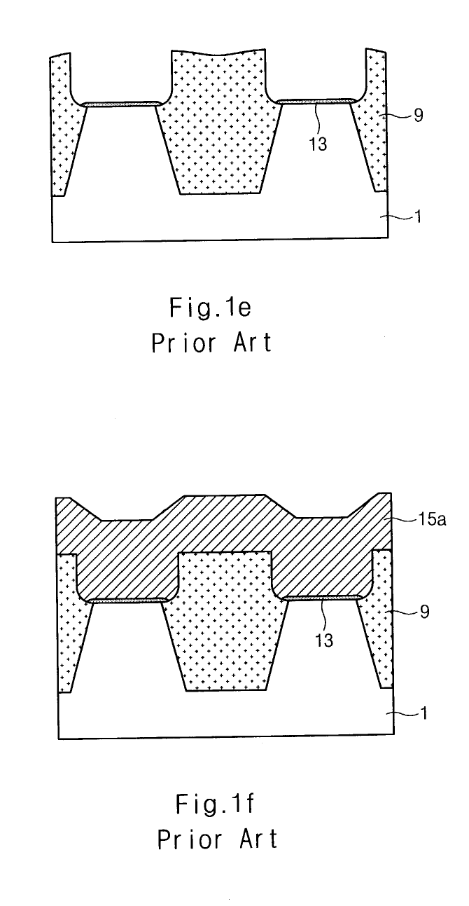

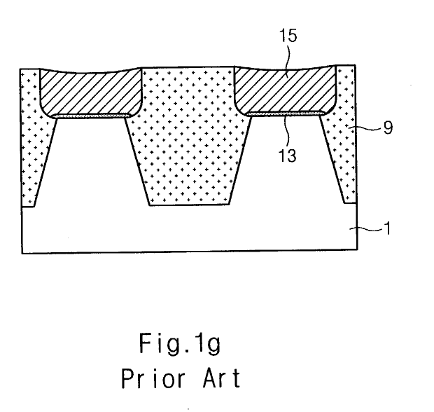

### DETAILED DESCRIPTION OF THE PREFERRED EMBODIMENTS

Methods of fabricating semiconductor device will now be described in more detail in reference to the accompanying drawings.

Again, all thicknesses presented are approximates and actual thickness may vary beyond the range disclosed without departing from the scope pf the disclosed methods.

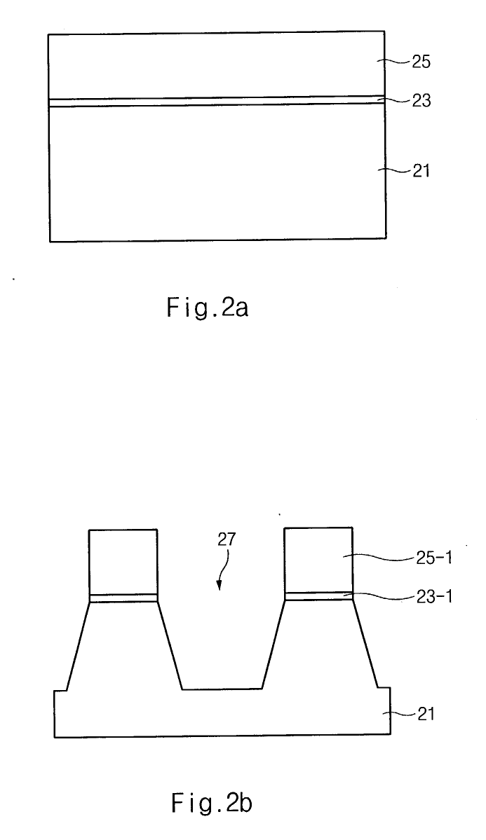

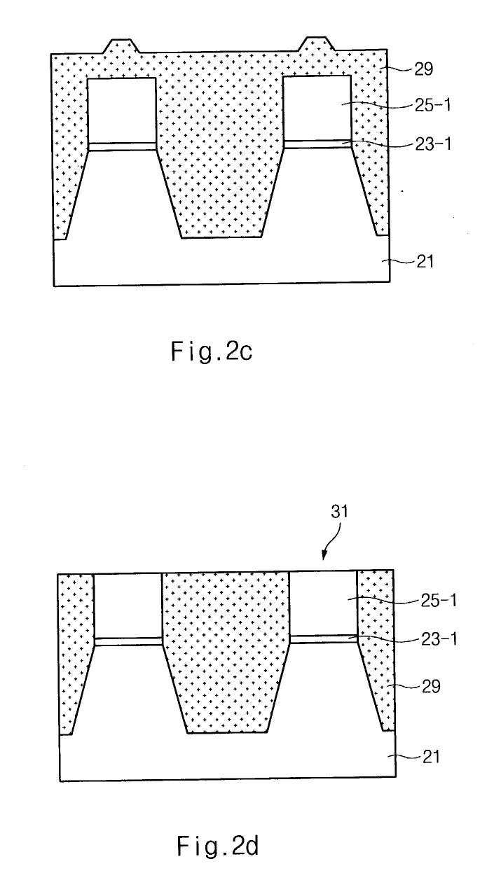

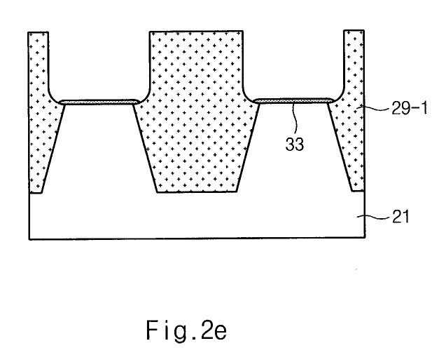

FIGS. 2a through 2g are diagrams illustrating methods of fabricating flash memory devices in accordance with a preferred embodiment of the present inventions.

Referring to FIG. 2a, a pad oxide film 23 is formed with a thickness ranging from 50 to 100 Å on the silicon substrate 21, and then a pad nitride film 25 is formed with a thickness ranging from 1500 to 2000 Å on the pad oxide film 23.

Referring to FIG. 2b, while a selective polishing process using mask (not shown) is performed on the resultant structure, the pad nitride film 25 at a thickness of 2500 Å, the pad oxide film 23 at a thickness of 100 Å and the silicon substrate 21 at a thickness of 3000 Å are sequentially removed.

As a result, a pad nitride film pattern 25-1, a pad oxide film pattern 23-1 and a trench 27 are formed.

Referring to FIG. 2c, a isolation oxide film 29 is formed with a thickness ranging from 5000 to 6000 Å on the entire surface of the above structure.

Referring to FIG. 2d, using the slurry of the present invention, a CMP process is performed on the remaining isolation oxide film 29 to separate a device active region 31 until the surface of the pad nitride pattern 25-1 is exposed.

Here, the pad nitride film pattern 25-1 is scarcely polished because the disclosed slurry has high etching selectivity to oxide films. As a result, the pad nitride film pattern 25-1 remains at its initial thickness ranging from 1500 to 2000 Å.

The CMP process comprises two steps. In the first step, the device isolation film is removed to have a portion on the pad nitride film by performing a CMP process using the conventional slurry for oxide films. Secondly, a target is completely removed by performing a CMP process using the slurry for oxide film of the present invention, the target that is the isolation oxide film above the pad nitride film.

For example, a portion of the device isolation film 29 is removed using the first conventional slurry for oxide films to have from 1 to 50%, more preferably, from 16 to 20% of its initial thickness.

Thereafter, a CMP process is performed on the remaining isolation oxide film 29 until the surface of pad nitride film pattern 25-1 is exposed.

As a result, the isolation oxide film 29 disclosed on the pad nitride film pattern 25-1 is completely removed to create the active region 31.

Referring to FIG. 2e, after the pad nitride film pattern 25-1 and the pad oxide film pattern 23-1 are selectively removed by wet-etching, an active region is exposed.

A tunnel oxide film 33 is formed by performing an oxidation process on the exposed surface of the active region.

The thickness of the isolation oxide film 29 is also maintained as much as the heights of the pad nitride film pattern 25-1. As a result, thickness difference in films according to the pattern density is decreased.

Accordingly, when the pad nitride film as the etching barrier film is formed in the disclosed method for forming patterns using the disclosed slurry, the thickness of nitride film can be reduced to about 500 Å.

As a result, the process cost and thickness difference of film can be reduced, thereby improving reliability of devices.

After a polysilicon(not shown) is formed on the resultant structure, and then a lower electrode of floating gate(not shown) is formed by performed a CMP process using the CMP slurry for polysilicon until the isolation oxide film 29 is exposed.

The floating gate formed by using the disclosed slurry maintains the initial thickness of the pad nitride film pattern 25-1.

I. Method of Fabricating Slurry of Present Invention.

### EXAMPLE 1

Slurry for Oxide Films Including Ceria(CeO₂)

According to the amount described in the following Table 1, CeO₂ as an abrasive is added in ultra pure water, stirred not to be condensed, and then alpha-cellulose (CAS #9004-34-6) as an additive is further added.

While the composition is stirred, hydrochloric acid as a pH adjusting agent is added in the composition to have pH 5. The composition is further being stirred for about 30 minutes until it is completely mixed and stabilized. As a result, slurry of the present invention having high selectivity to oxide films is fabricated.

TABLE 1

| | CeO₂ | Ultra Pure Water | Alpha-cellulose |
|---|---|---|---|
| A | 10 g | 1000 g | 5 g |
| B | 15 g | 1000 g | 5 g |
| C | 10 g | 1000 g | 10 g |

### EXAMPLE 2

Slurry for Oxide Films Using SiO₂ as an Abrasive

According to the amount described in the following Table 2, SiO₂ as an abrasive is added in ultra pure water, stirred not to be condensed, and then alpha-cellulose as an additive is further added.

While the composition is stirred, hydrochloric acid as a pH adjusting agent is added in the composition to have pH 5. The composition is further being stirred for about 30 minutes until it is completely mixed and stabilized. As a result, the disclosed slurry has a high selectivity to oxide films.

TABLE 2

| | SiO₂ | Ultra Pure Water | Alpha-cellulose |
|---|---|---|---|
| D | 10 g | 1000 g | 5 g |
| E | 15 g | 1000 g | 5 g |
| F | 10 g | 1000 g | 10 g |

II. Polishing Selectivity of Slurry of Present Invention.

### EXAMPLE 3

Using the slurry composition of the example 1, a CMP process is performed on silicon oxide films ‘OX’ and silicon nitride films ‘SiN’, respectively, at a head pressure and a polishing pressure of 5 psi, and at a table rotation frequency of 30 rpm. Table 3 shows the polishing amount and selectivity as a result of the CMP process.

TABLE 3

| | Polishing Amount of | polishing Selectivity |
|---|---|---|
| | oxide film (Ox, Å/min) | (Ox/SiN) |
| A | 3,000 | 80 |
| B | 4,000 | 50 |
| C | 2,500 | 60 |

### EXAMPLE 4

Using the slurry composition of example 2, a CMP process is performed on silicon oxide films ‘OX’ and silicon nitride films ‘SiN’, respectively, at a head pressure and a polishing pressure of 5 psi, and at a table rotation frequency of 30 rpm. Table 4 shows the polishing amount and selectivity as a result of the CMP process.

TABLE 4

| | Polishing Amount of | Polishing Selectivity |
|---|---|---|
| | oxide film (Ox, Å/min) | (Ox/SiN) |
| D | 3,000 | 80 |
| E | 3,000 | 50 |
| F | 2,500 | 60 |

As described earlier, the disclosed slurry has remarkably improved selectivity than the conventional slurry. If the isolation oxide film is polished using the disclosed slurry, it is possible to prevent an erosion of a pad nitride film and a dishing of a pad oxide film.

In addition, since thickness difference of a isolation oxide film according to the pattern density become decreased, patterns can be planarized, and damages of formed films during polishing processes can be reduced

As a result, patterns formed on the entire surface of wafer may have uniform concentration and thickness.

What is claimed is:

1. A CMP slurry composition for an oxide film comprising a solvent, an abrasive and an additive, the additive selected from the group consisting of:
a homo-polymer of hydrocarbon compound including carboxylic acid(—COOH) group, a homo-polymer of hydrocarbon compound including nitro(—NO₂) group and a homo-polymer of hydrocarbon compound including amide(—NH—CO—) group; a copolymer of hydrocarbon compound including carboxylic acid(—COOH) group, a copolymer of hydrocarbon compound including nitro(—NO₂) group and a copolymer of hydrocarbon compound including amide(—NH—CO—) group; and mixtures thereof,
wherein the composition has a pH ranging from 2 to 7.

2. The CMP slurry composition according to claim 1, wherein the pH of the composition ranges from pH 4 to 7.

3. The CMP slurry composition according to claim 1, further comprising hydrochloric acid as a pH adjusting agent.

4. The CMP slurry composition according to claim 1, wherein the additive is selected from the group consisting of alpha-cellulose, carboxymethylcellulose sodium salt, methyl vinyl ether, poly(acrylic acid), poly(ethylene glycol), poly-galacturonic acid and combinations thereof.

5. The CMP slurry composition according to claim 1, wherein the additive is present in amount ranging from 0.1 to 1.5 weight parts based on 100 weight parts of the solvent.

6. The CMP slurry composition according to claim 1, wherein the abrasive is Ceria(CeO₂) or silica(SiO₂).

7. The CMP slurry composition according to claim 6, wherein the CeO₂ is present in amount ranging from 0.5 to 2 weight parts based on 100 weight parts of the solvent.

8. The CMP slurry composition according to claim 6, wherein the SiO₂ is present in amount ranging from 10 to 33 weight parts based on 100 weight parts of the solvent.

9. The CMP slurry composition according to claim 1, wherein a polishing selectivity ratio of the slurry composition for nitride film:oxide film is 1:20˜1:200.

10. The CMP slurry composition according to claim 1, wherein a polishing selectivity ratio of the slurry composition for nitride film:oxide film is 1:50˜1:200.

11. A method of forming a semiconductor device, comprising:
(a) forming a pad oxide film and a pad nitride film on a substrate;
(b) selectively patterning the pad nitride film, the pad oxide film and the substrate to form a trench of a predetermined depth;
(c) depositing an isolation oxide film on the patterned pad nitride film, the pad oxide film and substrate; and
(d) performing a CMP process onto the resultant structure using the CMP slurry composition of claim 1 until the pad nitride film is exposed.

12. The method according to claim 11, wherein the (d) step comprises:
a first step of performing a CMP process using a slurry for an oxide film of which a polishing selectivity ratio for nitride film:oxide film is 1:2˜1:4 until a predetermined thickness of the isolation oxide film remains; and
a second step of performing a CMP process using a slurry of claim 1 until the pad nitride film is exposed.

13. The method according to claim 12, wherein the first step is performed until the thickness isolation oxide film on the pad nitride film ranges from 1 to 50% relative to the thickness before the CMP process.

14. The method according to claim 12, wherein the slurry for an oxide film comprises an abrasive of SiO₂ and has a pH ranging from 7 to 8.
